(19) United States
(12) Patent Application Publication
(10) Pub. No.: US 2012/0186633 A1
(43) Pub. Date: Jul. 26, 2012

(54) COMPOSITE INSULATING PANEL

(76) Inventors: James Carolan, County Cavan (IE); Gregory Flynn, County Louth (IE)

(21) Appl. No.: 13/499,035

(22) PCT Filed: Nov. 4, 2010
(86) PCT No.: PCT/IE10/00065

§ 371 Date: Mar. 29, 2012

(30) Foreign Application Priority Data
Nov. 5, 2009 (IE) 2009/0854
Mar. 3, 2010 (IE) 2010/0123

(51) Int. Cl. H01L 31/048; H01L 31/18

(52) U.S. Cl. 136/251; 438/57; 257/E31.001

(57) ABSTRACT

A photovoltaic solar collector is mounted to a profiled external sheet of an underlying composite insulating panel. The solar collector comprises a photovoltaic sheet and a protective translucent cover for the photovoltaic sheet. A first adhesive layer is provided between the photovoltaic sheet and the translucent cover. A second adhesive layer is provided between the underside of the photovoltaic sheet and the external surface of the composite panel upper or external sheet. The adhesive layers may be of the same hot melt adhesive. In the invention sheets of the photovoltaic, the adhesive, and the cover are drawn from supply reels, are cut to length, and then laid on top of the upper sheet of the insulated panel. Using a pressure laminating process the various layers are heated and pressed to adhere to and conform to the outer sheet of the insulated panel.

With increasing energy costs there is a need for a more thermally efficient system for cladding a building.

This invention is directed towards providing an improved insulating panel which will address this issue.

### STATEMENTS OF INVENTION

According to the invention there is provided a panel comprising a profiled metal sheet and a photovoltaic solar collector sheet laminated to the external surface of the metal sheet.

In one embodiment the panel comprises an insulating body bonded to the internal surface of the metal sheet.

In another aspect the invention provides a composite insulating panel comprising:—
an external sheet;
an internal sheet;
an insulating body between the external sheet and the internal sheet, and
a photovoltaic solar collector sheet laminated to the external surface of the external sheet.

In one case the external sheet is profiled and the solar collector substantially follows the profile of the profiled external sheet.

Preferably there is a translucent cover for the photovoltaic sheet.

In one case the panel comprises an adhesive layer between the photovoltaic sheet and the cover.

In one embodiment there is an adhesive layer between the photovoltaic sheet and the external sheet.

In one case the solar collector comprises a photovoltaic sheet, a translucent cover for the photovoltaic sheet, a first adhesive layer between one side of the photovoltaic sheet and the cover layer, and a second adhesive layer on the other side of the photovoltaic sheet.

In one embodiment the second adhesive layer comprises a thermoplastic polyurethane (TPU) adhesive.

The first adhesive layer may be of a hot melt adhesive such as ethylene vinyl acetate (EVA) material.

In one case the translucent cover is of a plastics material such as ethylene tetrafluoroethylene material.

In one embodiment the external sheet comprises a plurality of longitudinally extending ribs and the photovoltaic sheet follows the profile of the ribs.

In one embodiment wherein a plurality of photovoltaic solar collector sheets are laminated to the external sheet of the panel. The photovoltaic sheets may be spaced apart along and/or across the external sheet of the panel, at least some of the photovoltaic sheets being electrically interconnected.

In one case the external sheet of the panel comprises a plurality of raised projections and the photovoltaic sheets are located between the projections.

The panel may comprise raised projections such as raised crowns. In one case the raised projections are of generally trapezoidal form and extend longitudinally along the length of the panel. The raised projections may comprise a side underlap projection and a side overlap projection for jointing adjacent like panels.

The raised projections may comprise a side underlap projection and a side overlap projection for jointing adjacent panels.

In one case the external sheet comprises a male projecting part and a female recess part for jointing adjacent panels.

The internal sheet may comprise a male projecting part and a female recess part for jointing adjacent panels.

In one embodiment the insulating body comprises a plurality of longitudinally extending conduit means. The external sheet may comprise raised projections extending longitudinally along the length of the panel and the conduit means may be defined in part by the inner face of the raised projection.

In a preferred embodiment the insulating body comprises a foam such as a polyisocyanurate foam material, or a phenolic foam material.

In one embodiment the external sheet comprises a steel material.

In one embodiment the internal sheet comprises a metallic material, such as a steel material.

In one case the panel comprises a roof panel.

The invention also provides a roof assembly comprising a plurality of composite panels of the invention.

The invention also provides method for manufacturing a composite insulated panel with a photovoltaic solar collector sheet attached thereto comprising the steps of:—
providing an insulation panel comprising an external sheet, an internal sheet and an insulating body between the external sheet and the internal sheet; and
laminating a solar collector sheet to the external sheet of the panel.

In one embodiment the method comprises providing a first adhesive sheet between the external sheet of the panel and the solar collector sheet.

The method may comprise providing a translucent cover sheet over the photovoltaic solar collector sheet and laminating the panel external sheet, solar collector sheet and the translucent cover sheet. A second adhesive sheet may be provided between the solar collector sheet and the translucent cover sheet.

In one embodiment the method comprises providing a plurality of separate photovoltaic solar collector sheets spaced-apart along and/or across the panel external sheet and simultaneously laminating at least some of the solar collector sheets to the panel external sheet.

The method may comprise electrically interconnecting at least some of the separate solar collector sheets.

A method for manufacturing a composite insulated panel with a photovoltaic solar collector sheet attached thereto substantially as hereinbefore described.

### BRIEF DESCRIPTION OF THE DRAWINGS

The invention will be more clearly understood from the following description thereof given by way of example only, in which:—

FIG. 1 is a perspective, partially cross sectional view of an insulating panel of the invention;

FIG. 2 is an enlarged cross sectional view of a portion of the panel of FIG. 1;

FIG. 3 is an exploded view of the panel of FIGS. 1 and 2;

FIGS. 4 to 7 are isometric views of various steps used in the manufacture of the panel;

FIG. 8 is another isometric view of the panel of the invention;

FIG. 9 is an isometric view of a photovoltaic solar collector sheet;

FIG. 10 is an exploded view of another panel according to the invention;

FIG. 11 is an isometric, partially cross sectional view of the panel of FIG. 10;

FIG. 12 is an enlarged cross sectional view of portion of the panel of FIG. 11;

FIG. 13 is a perspective view of a panel of the invention with adjacent photovoltaic solar collector sheets mounted thereto at one end;

FIG. 14 is a view similar to FIG. 13 with further photovoltaic solar collector sheets;

FIG. 15 is a view similar to FIG. 14 with further photovoltaic solar collector sheets;

FIG. 16 is a perspective view of an assembly of insulating panels of the invention with photovoltaic solar collector sheets in situ;

FIG. 17 is a diagram illustrating a panel with another arrangement of photovoltaic solar collector sheets;

FIG. 18 is an isometric view of a further panel according to the invention;

FIG. 19 is a cross sectional view of the panel of FIG. 18;

FIGS. 20 and 21 are cross sectional views of a further panel according to the invention;

FIGS. 22 and 23 are cross sectional views of another panel according to the invention;

FIG. 24 is a cross sectional view of another panel according to the invention;

FIG. 25 is a cross sectional view of a further panel according to the invention;

FIG. 26 is a diagram illustrating the panel of FIG. 25 with a photovoltaic solar collector unit mounted thereto; and

FIGS. 27 to 44 are cross sectional views of various examples of panels according to the invention.

### DETAILED DESCRIPTION

Referring to the drawings there is illustrated an insulating panel 1 according to the invention comprising a first or external sheet 2, a second or inner sheet 4 with an insulating body, in this case an insulating foam 5 therebetween. The foam may, for example be a polyisocyanurate foam or a phenolic foam. In this case the panel 1 is a roof panel 1 comprising a profiled external sheet 2 which is typically of metal, such as galvanised steel. The profile in this case comprises a plurality of elongate strengthening ribs 30 which extend longitudinally along the length of the external sheet 2. In this case there are also raised crowns 3. The crowns 3 in this case are of generally trapezoidal form and extend longitudinally along the length of the panel. In this case there is a side underlap projection or crown 31 on one side of the upper sheet 2 and a side overlap projection or crown 36 on the opposite side of the panel. In use, adjacent like panels are overlapped by overlapping the overlap crown 36 of one panel with the underlap crown 31 of an adjacent panel. Similarly, the panels typically have end underlap and overlap features for end lapping of adjacent like panels. The inner metal liner sheet 4 may be of painted galvanised steel.

A photovoltaic solar collector unit 10 is mounted to the external sheet 2 of the underlying insulating panel. The solar collector 10 comprises a photovoltaic sheet 20 and a translucent cover 21 for the photovoltaic sheet 20. A first adhesive layer 22 is provided between the photovoltaic sheet 20 and the translucent cover 21. A second adhesive layer 23 is provided between the underside of the photovoltaic sheet 20 and the external surface of the composite panel upper or external sheet 2. The cover 21 is of a suitable protective plastics material such as ethylene tetrafluoroethylene (ETFE) which has a high melting temperature and excellent chemical and electrical resistance properties. It is resilient and self cleaning compared to glass, an ETFE film transmits more light and costs substantially less.

The adhesive layers are preferably of a hot melt adhesive to facilitate lamination. In one case the adhesive layer 22 is of ethylene vinyl acetate (EVA).

For enhanced bond strength the adhesive layer 23 between the external sheet 2 and the photovoltaic sheet 20 comprises a thermoplastic polyurethane (TPU) material.

The composite panel may be manufactured by a process as described in our GB 2309412 A, the entire contents of which are herein incorporated by reference.

The panels are manufactured with the external sheet 2 lowermost. For the next steps in the process of the invention the panels are turned so that the external sheet 2 is uppermost.

In the invention sheets of the photovoltaic 20, the adhesives 22, 23, and the cover 21 are drawn from supply reels, are cut to length, and then laid on top of the upper sheet 2 of the insulated panel. Using a pressure laminating process the various layers are heated and pressed to adhere to and conform to the profile of the outer sheet 2 of the insulated panel including the reinforcing ribs and in this case also the crowns 3.

A composite insulating panel may therefore be fully covered by photovoltaic cells thereby utilising the full panel surface for energy collection.

In the invention, rather than utilising a pre-prepared photovoltaic laminate assembly, some elements of the photovoltaic assembly are used individually and the assembly is laminated to the profiled composite insulating panel in one step. In the invention a separate carrier for the photovoltaic is not required as the photovoltaic is bonded directly to the external sheet of the composite insulating panel.

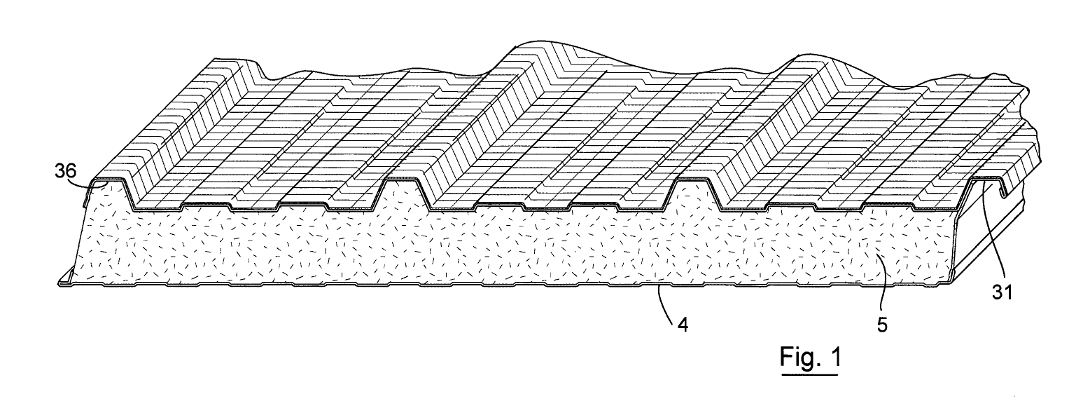

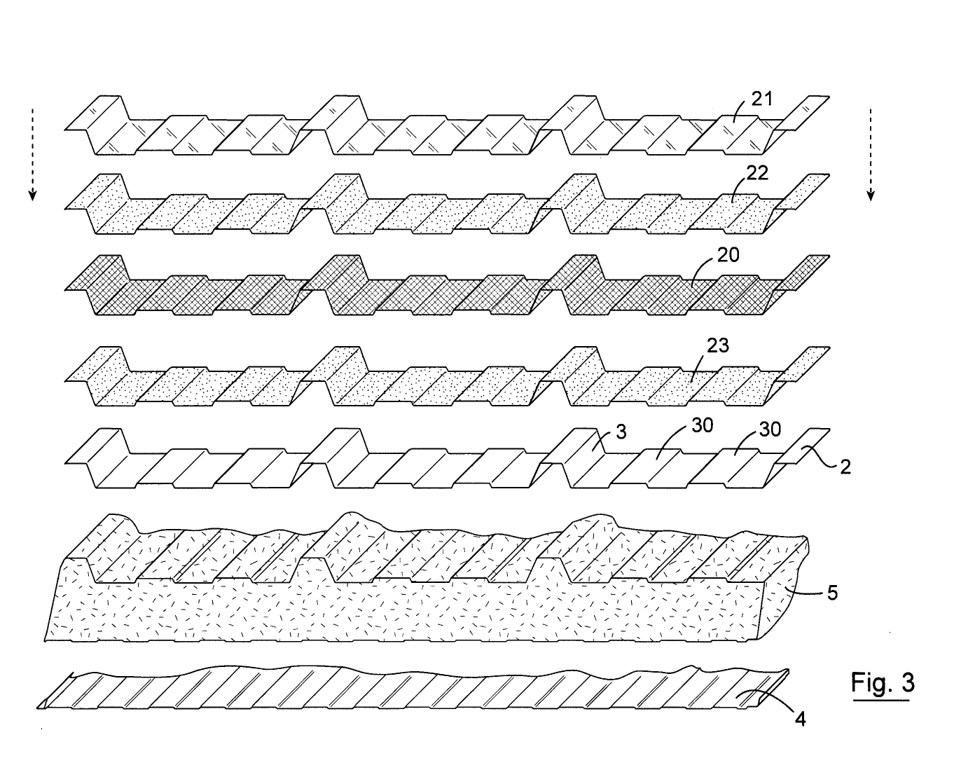

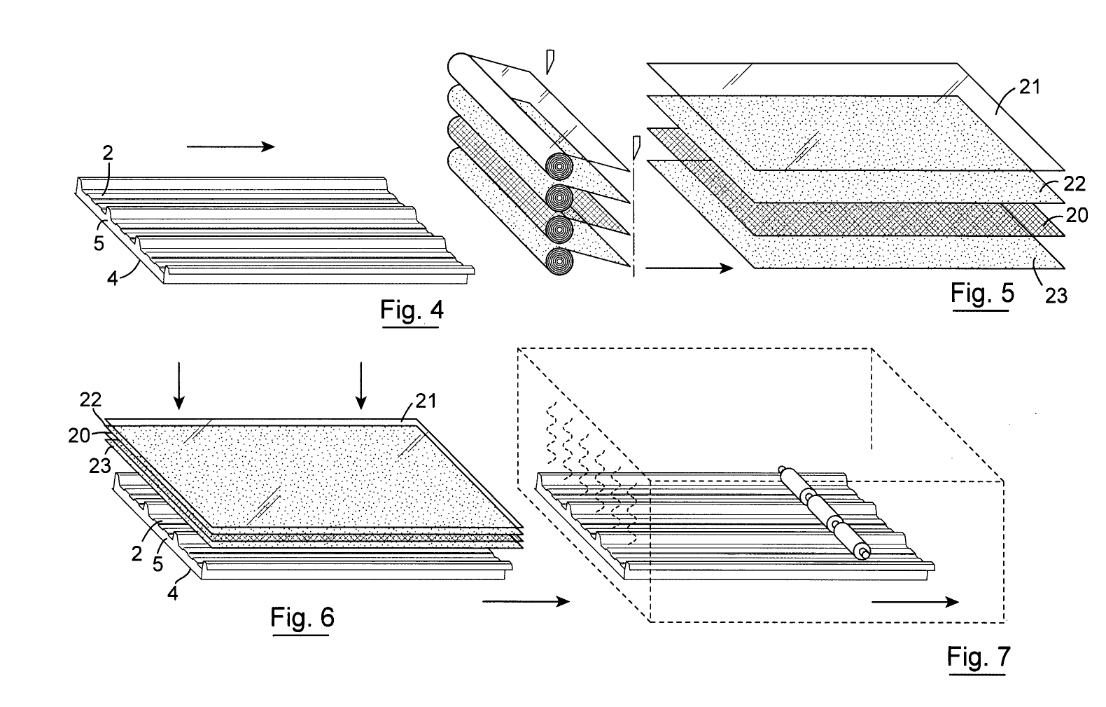

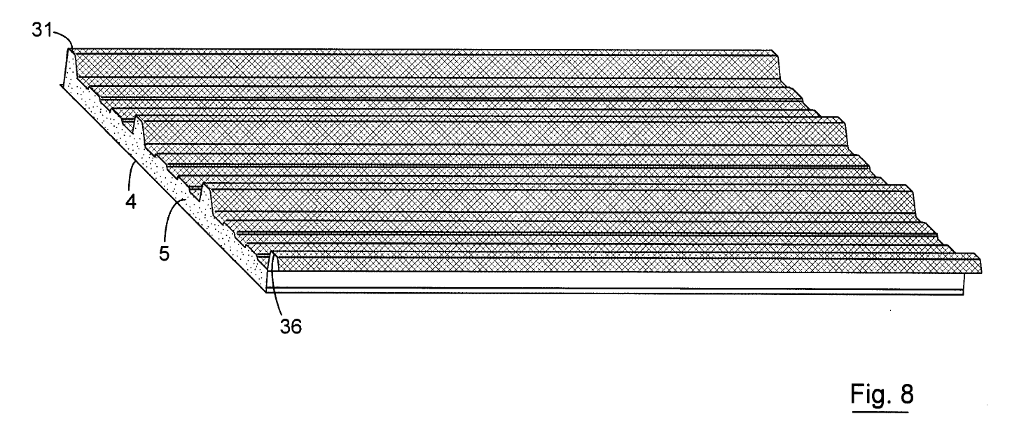

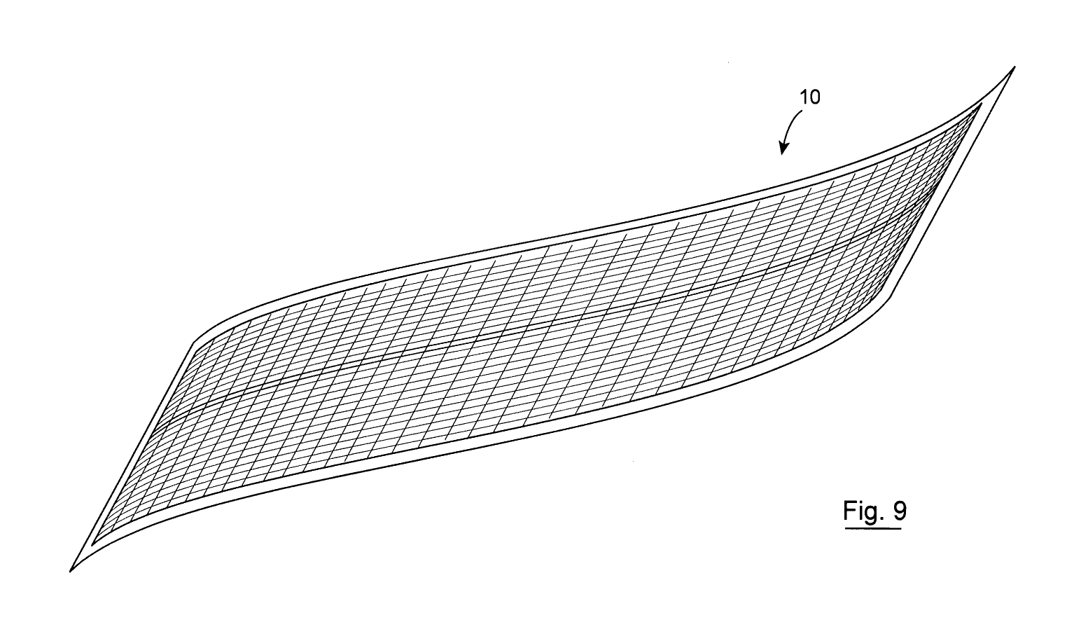

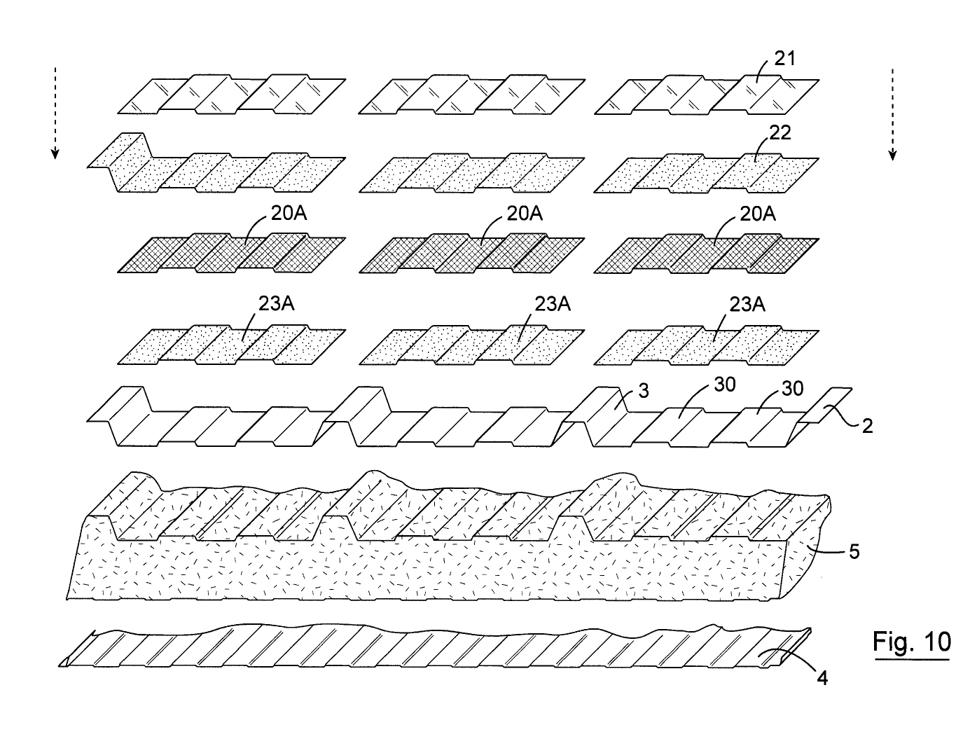

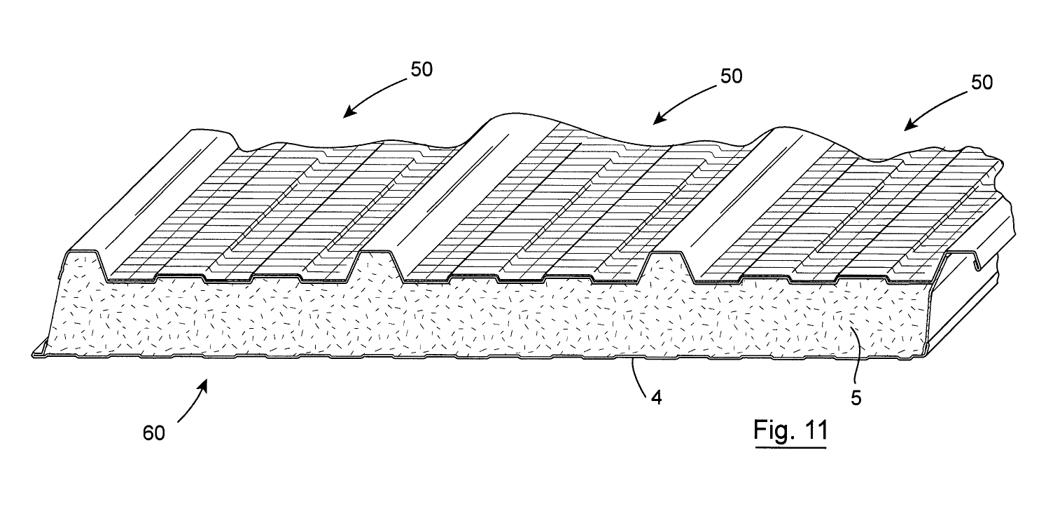

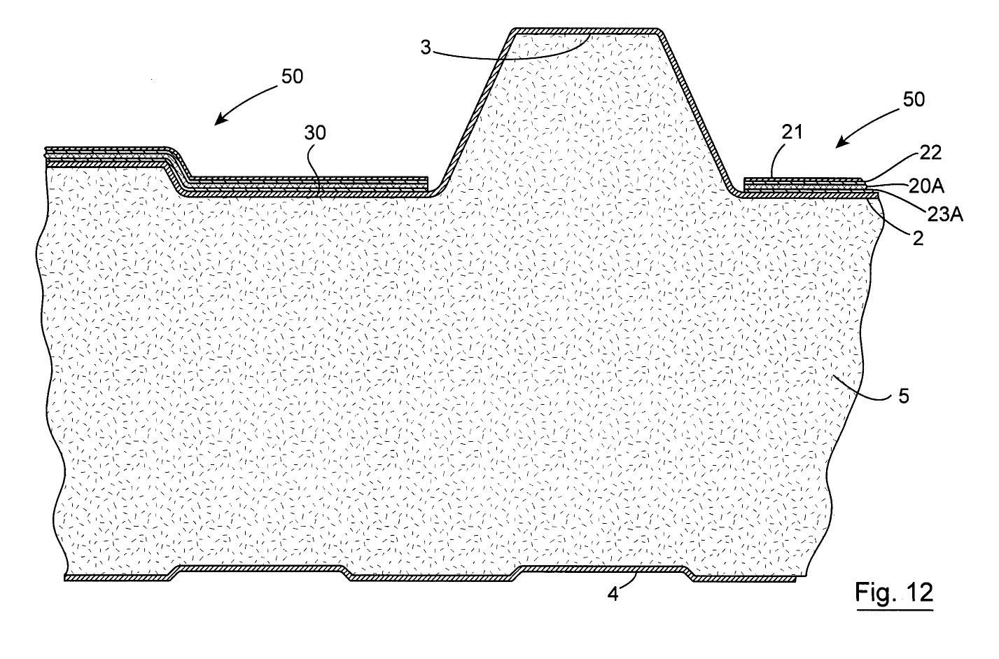

Referring to FIGS. 10 to 12 there is illustrated another panel according to the invention in which parts similar to those of FIGS. 1 to 9 are assigned the same reference numerals.

In this case the photovoltaic sheet comprises a number of elongate strips 20A which are laminated to the external sheet 2 of the panel intermediate the crowns 3. The strips 20A follow the contour of the external sheet 2 and in particular the profile of the reinforcing ribs 30. Because the photovoltaic sheet 20A does not in this case extend over the crowns 3 the panels are more easily manufactured and are less costly. In particular, as the photovoltaic sheet does not extend over the raised crowns projections it is easier to laminate to the external sheet of the panel. The photovoltaic sheets located between the raised crowns are readily electrically interconnected, for example by flexible wires/connections extending over the raised crowns. There may be a small difference in efficiency of solar collection but this is not significant in the context of the overall efficiency of the panel.

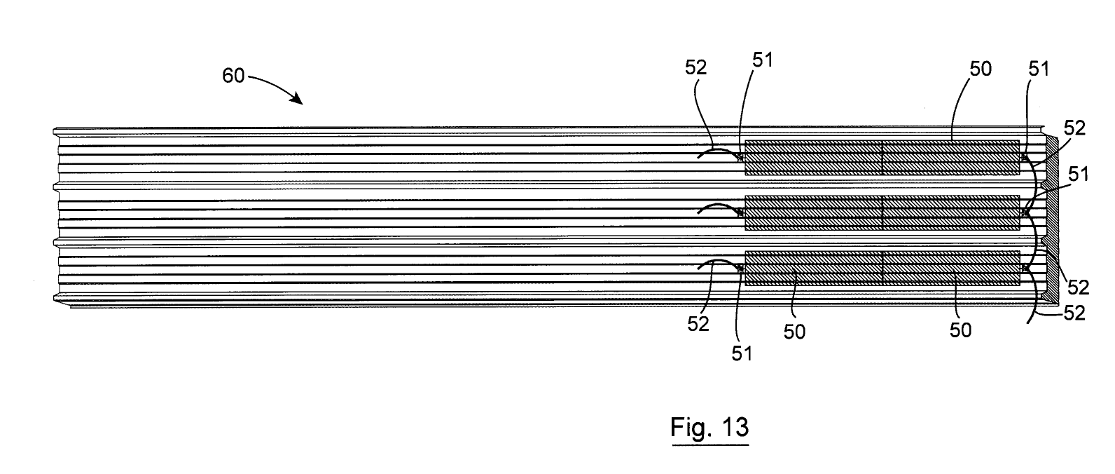

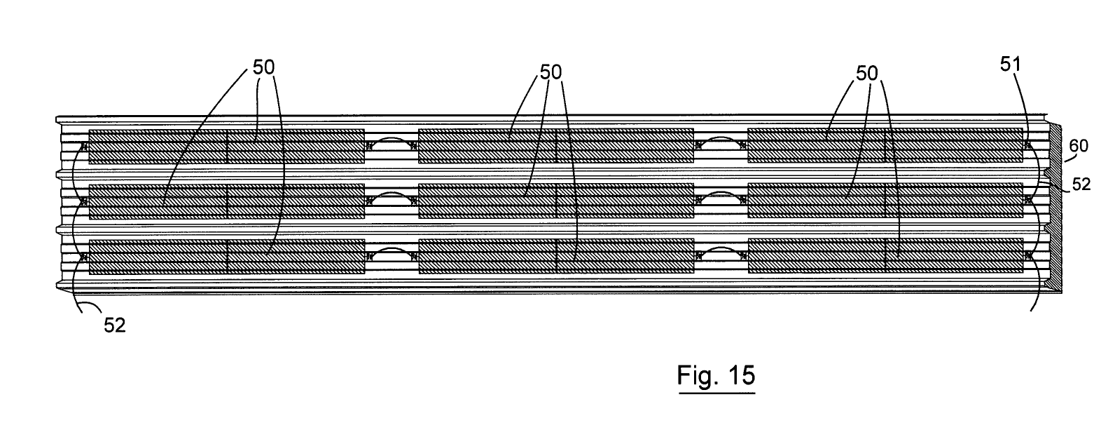

Referring to FIGS. 13 to 16 a number of separate photovoltaic solar collector units 50 are illustrated. Each of these corresponds to the photovoltaic strips 20A, adhesive layers 22, 23 and protective translucent cover layer 21. Each solar collector unit 50 has terminations 51 and adjacent solar collector units 50 are electrically interconnected by connecting links 52. In a first stage a number (in this case three) separate solar collector units 50 are laminated to the external sheet 2 of an insulating panel at one end as described above. The photovoltaic units 50 are electrically interconnected either before or after lamination forming a solar collector module comprising three units 50 (FIG. 13).

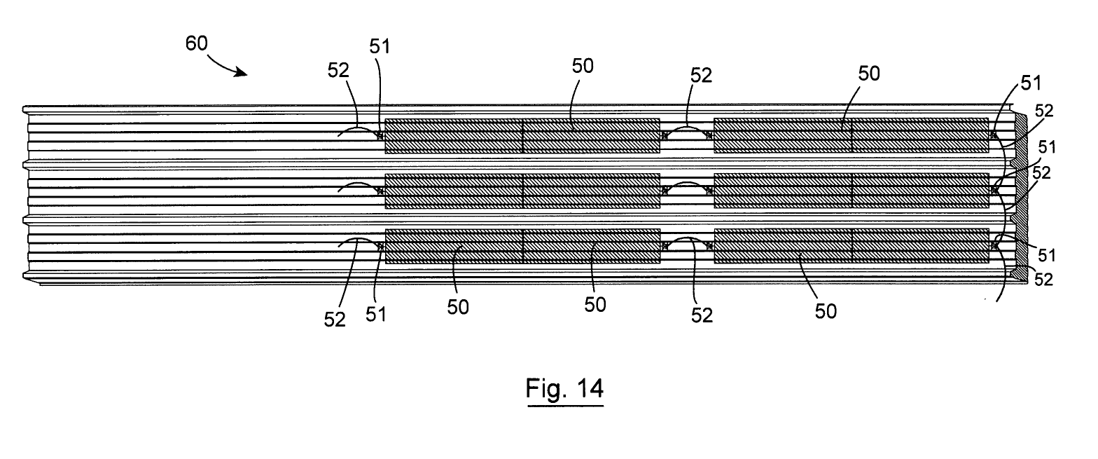

The insulating panel with the first solar collector module in situ is then indexed through a laminator and in the same way a second photovoltaic solar collector module of three units 50 is then laminated to the external sheet 2 of the insulating panel (FIG. 14).

The insulating panel with the first and second solar collector modules in situ are the indexed through the laminator and in the same way a third photovoltaic solar collector module of three units is then laminated to the external sheet 2 of the insulating panel (FIG. 14).

The modules may be electrically interconnected at any convenient stage such as between indexing of the insulating panel through a laminator or after all of the modules have been laminated to the panel.

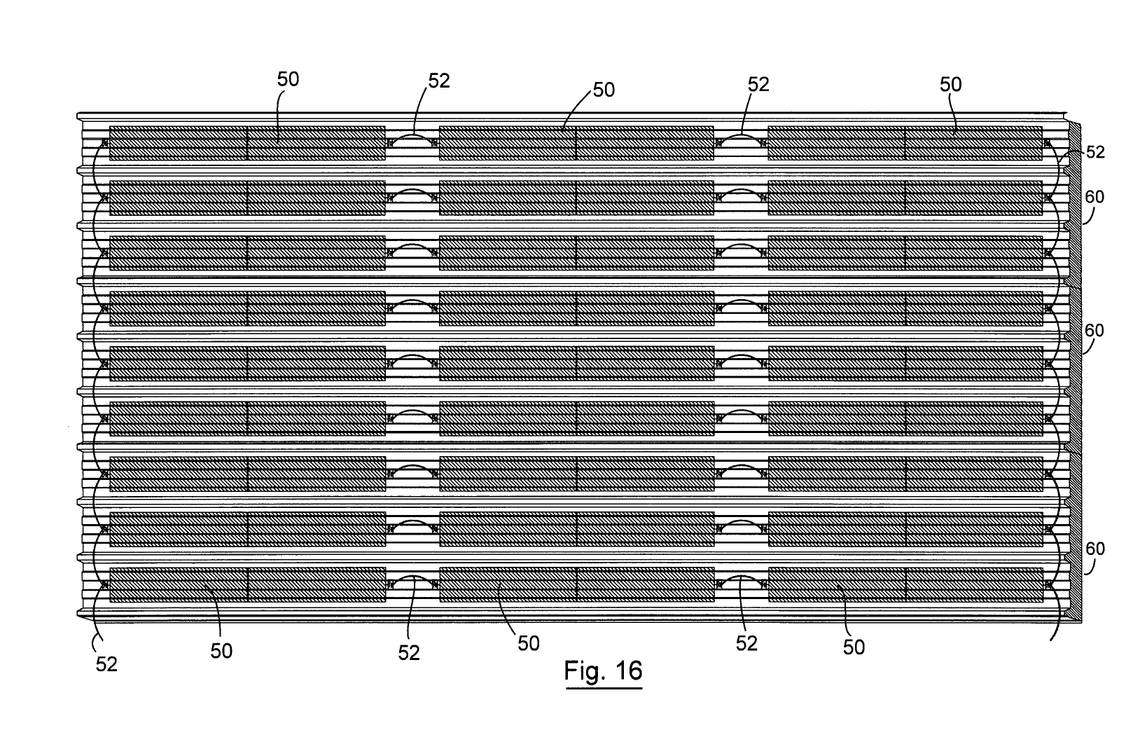

On site, a number of the insulating panels are jointed together and the solar collector modules of adjacent panels are interconnected (FIG. 16).

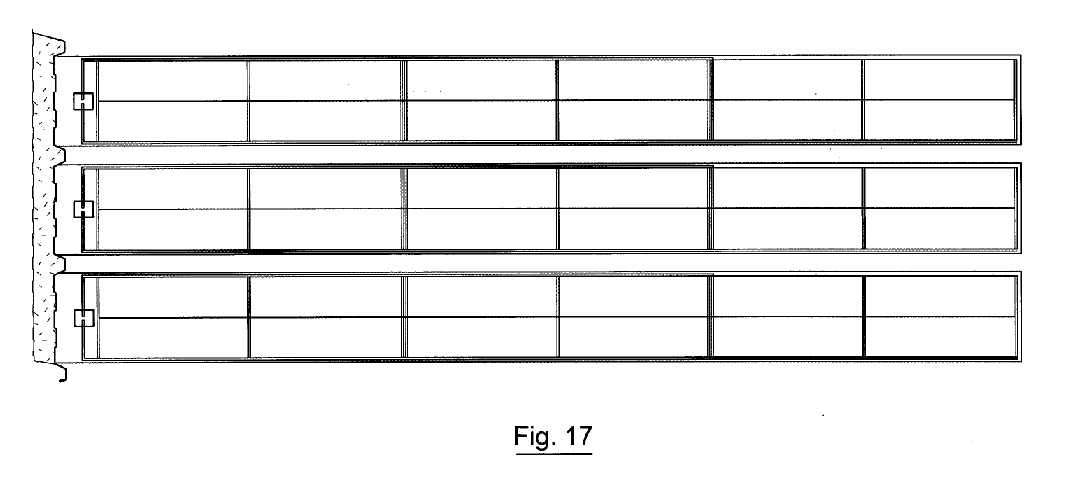

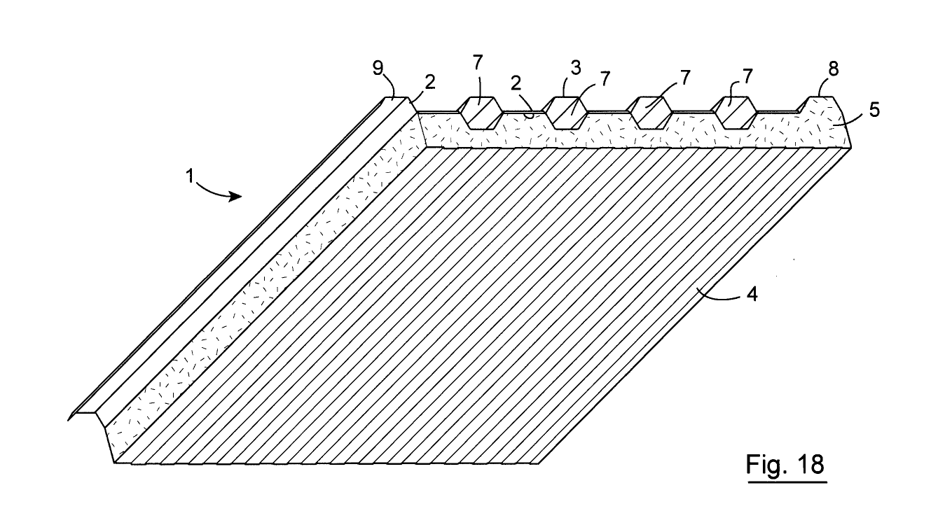

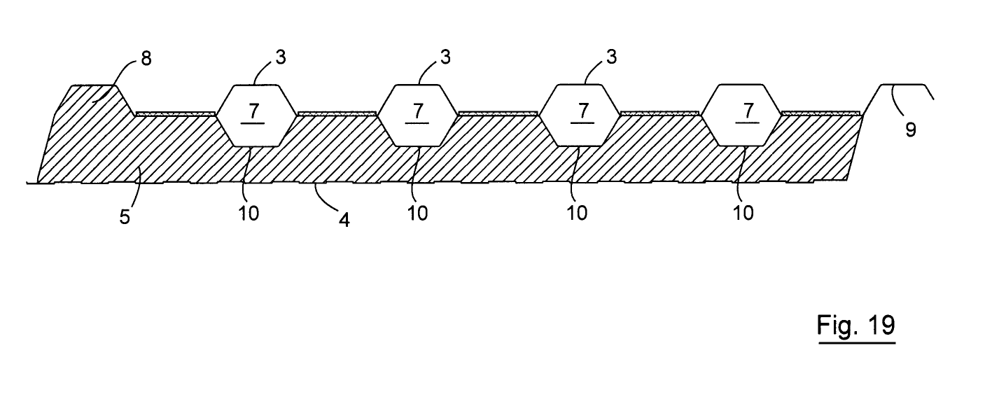

Referring to FIGS. 18 and 19 there is illustrated another panel according to the invention in this case the foam defines a plurality of longitudinally extending conduit means 7 through which a suitable heat exchange medium such as air may be circulated. The panel thus has an integral heat collecting means provided in some of the crowns 3 of the external sheet which are devoid of insulation 5. The conduits 7 extend through the crowns 3 and air is circulated through the conduits 7. The conduits 7 run through the roof and/or wall in the external envelope of the building and the air absorbs solar energy. Conduits 7 may alternatively or additionally be provided in floor panels for heat circulation. The warmed air may be pumped back into the building to provide heat to the building space. Once the heated air passes through the building and transfers its energy, it may flow back to the conduit in the roof and/or wall and/or floor panels and the process may be repeated in a closed loop.

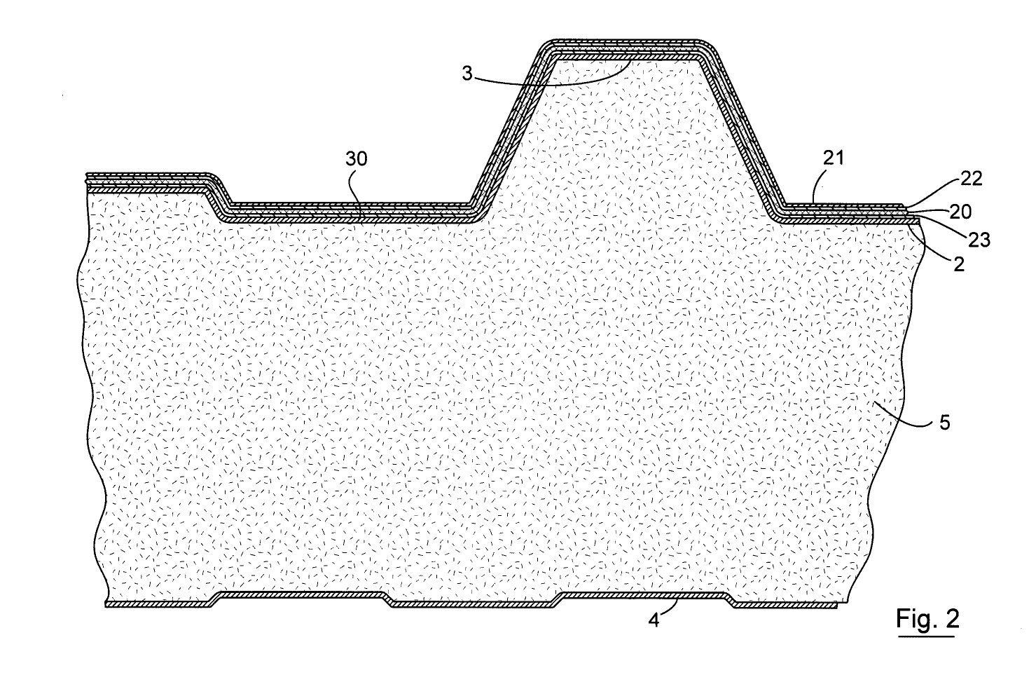

Barriers, in this case in the form of a membrane such as a tape or foil 10 are located below the crowns 3 to prevent foam entering the crowns 3 and in this case also to create additional foam-free voids below the crowns 3. This creates an enlarged void space through which air may be circulated to enhance the solar collecting efficiency of the panel. Referring in particular to FIGS. 2(a) the barriers 10 in this case have projecting side portions or legs 11 which may be attached, for example by adhesive to the inner face of the outer skin 3 of the panel. There is a free area 12 between individual barriers 10 to which the foam may directly bond to ensure direct foam bonding to the skin 3. The barriers 10 may be any suitable material such as foil or tape.

The barrier 10 is not planar and can be used to define conduits of any desired size and/or shape. The barrier 10 has a pair of longitudinally extending transversely spaced-apart sides, 11 defining a plane therebetween and the barrier extends outside of said plane. The barrier can therefore be extended into the main body of the foam. The barrier can extend inwardly of the first sheet 2 and/or the second sheet 4 to provide a conduit of any desired size and shape. The first and/or second sheets may be profiled and at least some of the profile recesses may form a conduit. To increase the heat transfer capabilities the conduit may be larger than the recess defined by the profile of the sheet. There may be a foam recess part and a profile recess part of the conduit. These may be oppositely directed to enlarge the size of the conduit. In one case the foam recess part is of a shape which is substantially a minor image of the profile recess part.

It will be noted that the cross sectional area of the void space 7 created between the crowns 3 and the barriers 10 is relatively large for optimisation of air flow and heat transfer. Utilising barriers of different size, the void area can be adjusted to suit the particular requirements of a building.

In this case an underlap crown 8 is filled with insulation foam so that when overlapped on assembly with an overlap hook 9 of an adjacent panel, the panels at the joint can be readily jointed or stitched together. The compressive strength at the joint is enhanced.

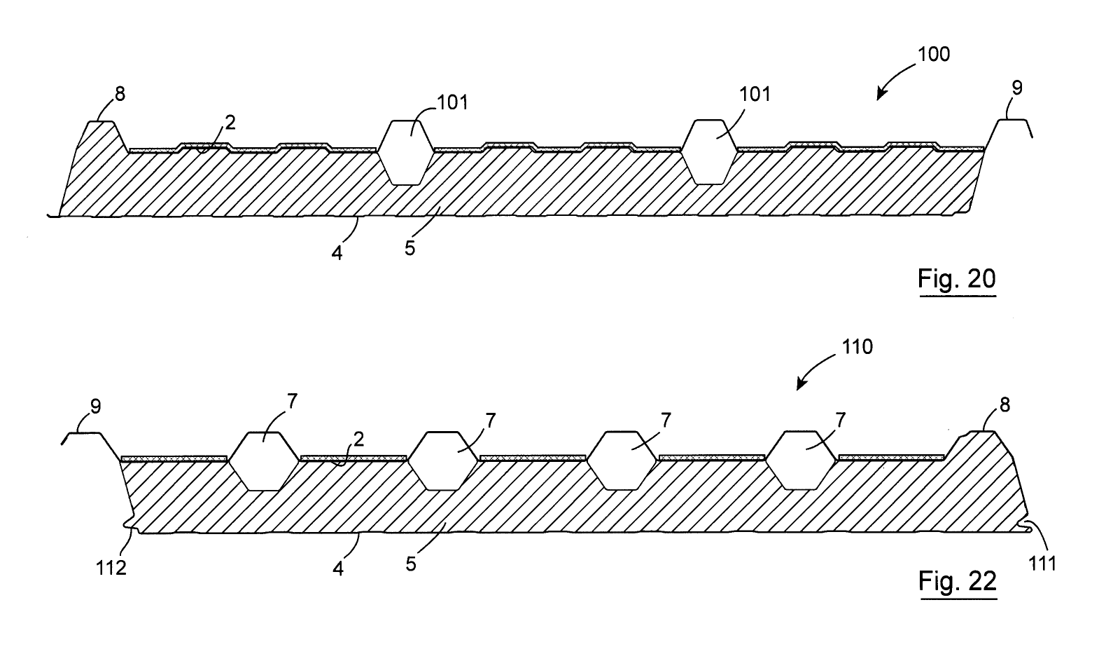

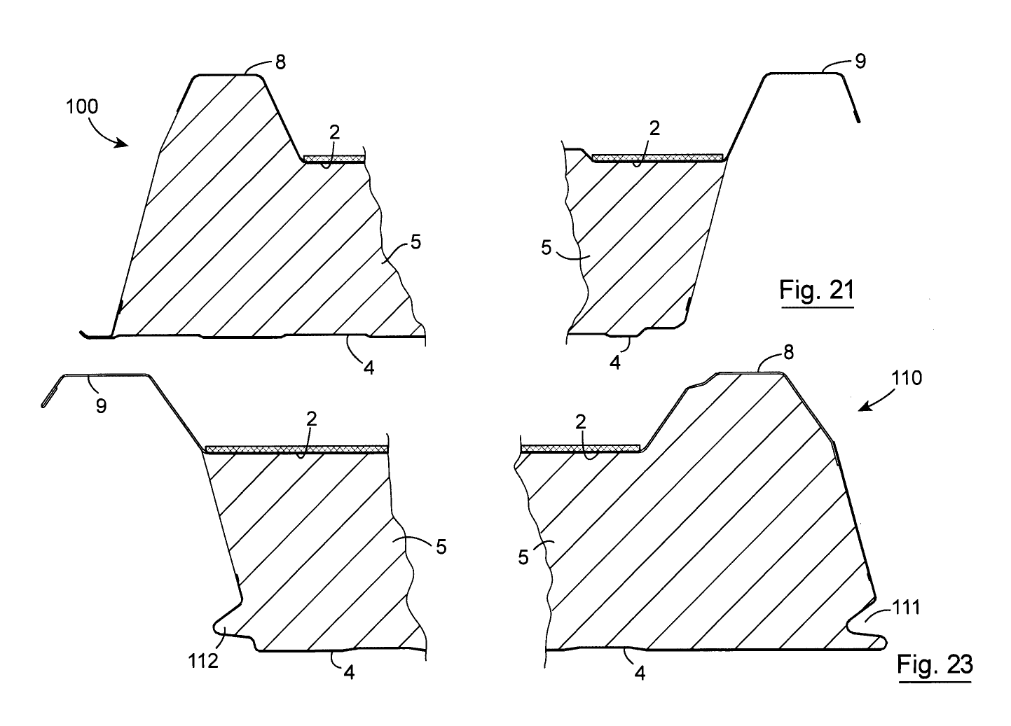

The panel 100 of FIGS. 20 and 21 with two conduits 101 will have the ability to collect and circulate energy but will not be as efficient as the panel of FIGS. 18 and 19.

The panel 110 of FIGS. 22 and 23 is similar to that of FIGS. 18 and 19. In this case the panel has engagement formations in the form of recesses 111 and projections 112 for engagement of adjacent like panels.

Such interengagement features may be provided by either the external panel sheet and/or the internal panel sheet. Interengagement features may be provided on any of the panels of the invention.

The panels of the invention may or may not have projections/crowns on their external face. These projections/crowns may or may not be used to provide conduits 7. When used, conduits 7 may be provided in any desired shape at any desired location of the panel.

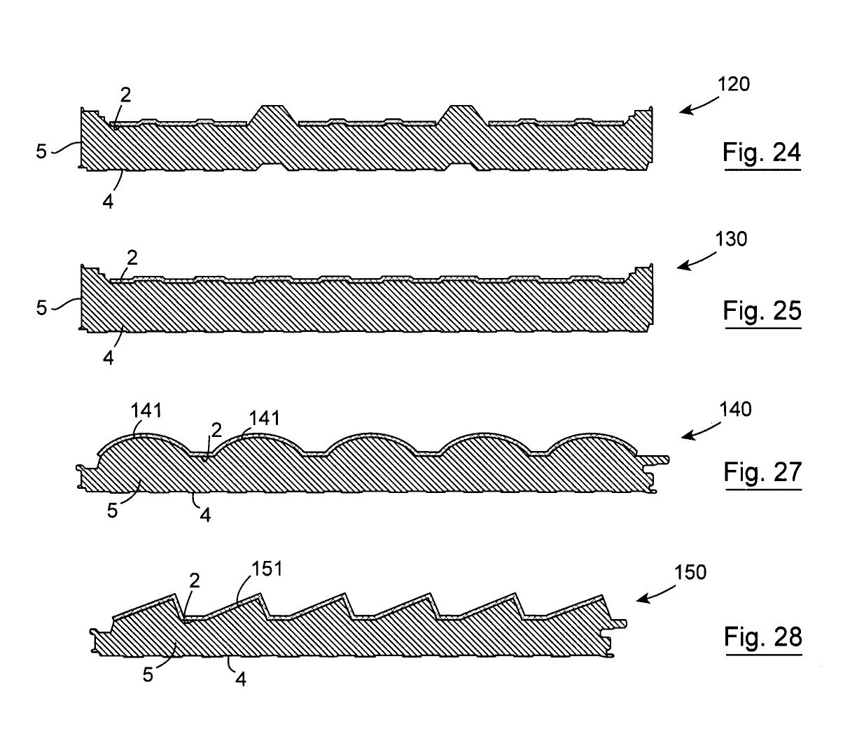

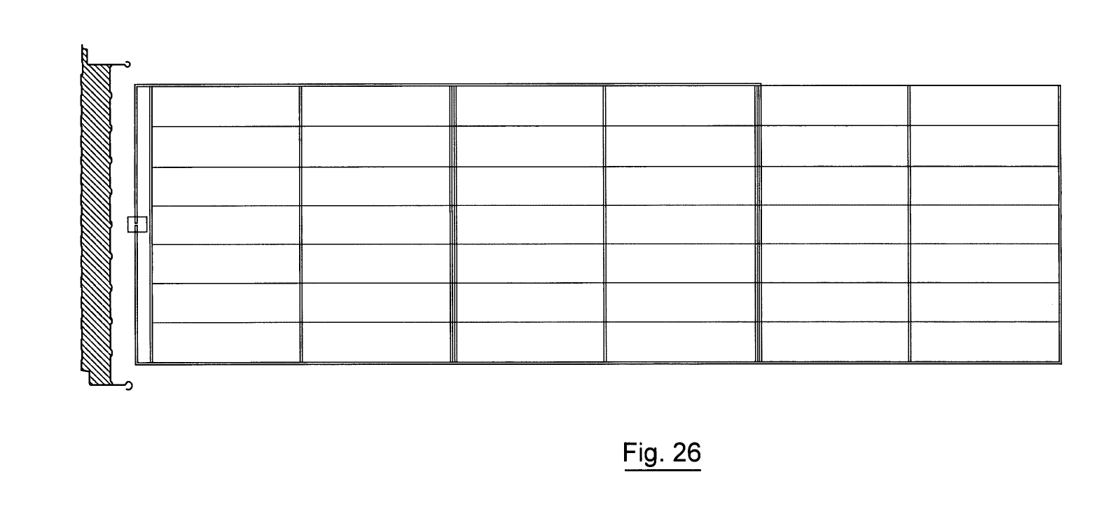

Further panels 120, 130 according to the invention are illustrated in FIGS. 24 and 25. FIG. 26 illustrates a photovoltaic solar collector sheet mounted to the panel of FIG. 25.

The panel 140 of FIG. 27 is similar to the panels described above except that the crowns/projections 141 are of curvilinear—such as accurate—shape. In the panel 150 of FIG. 28 the crowns/projections 151 are of triangular shape.

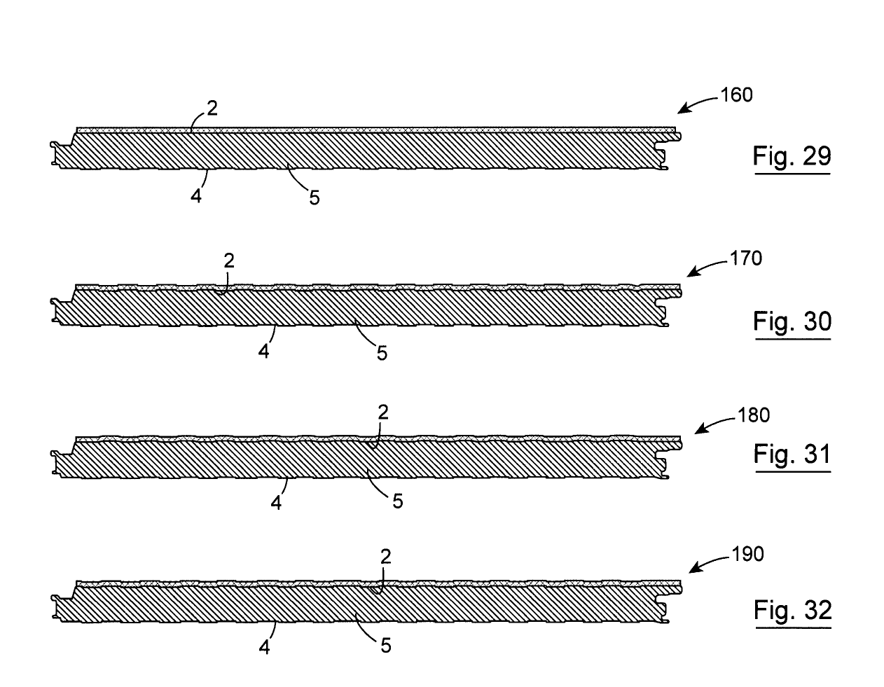

The panels 160, 170, 180, 190, of FIGS. 29 to 32 are of similar profile and are generally flat with external sheets 2 and/or internal sheets 4 with or without small formations such as microribs.

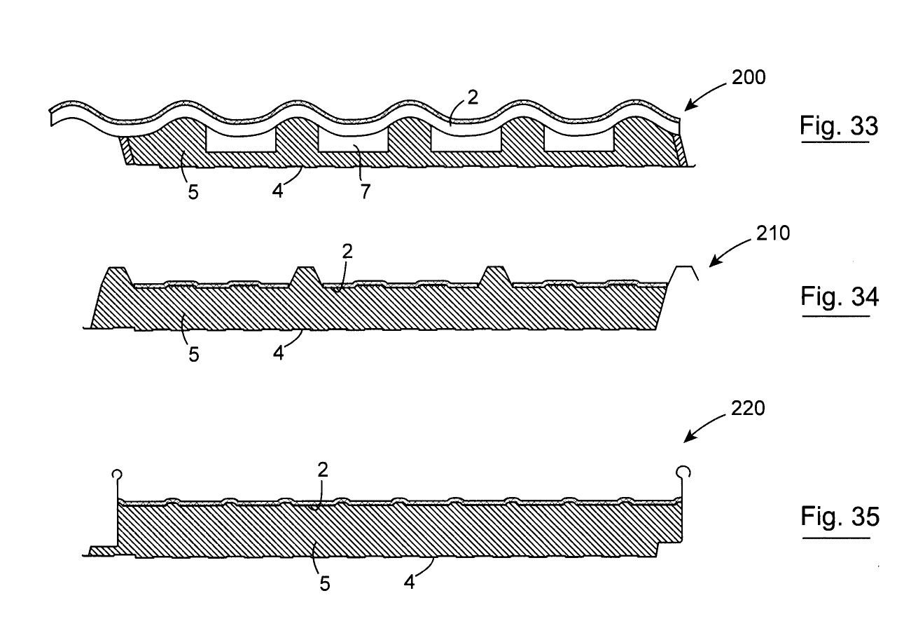

Referring to FIG. 33, in this case a panel 200 is a roof tile panel with an external sheet of undulating or corrugated form. Panels of this type are described in UK-A-2384500, the entire contents of which are incorporated herein by reference. The panels 210 and 220 of FIGS. 34 and 35 respectively are roof panels of different types.

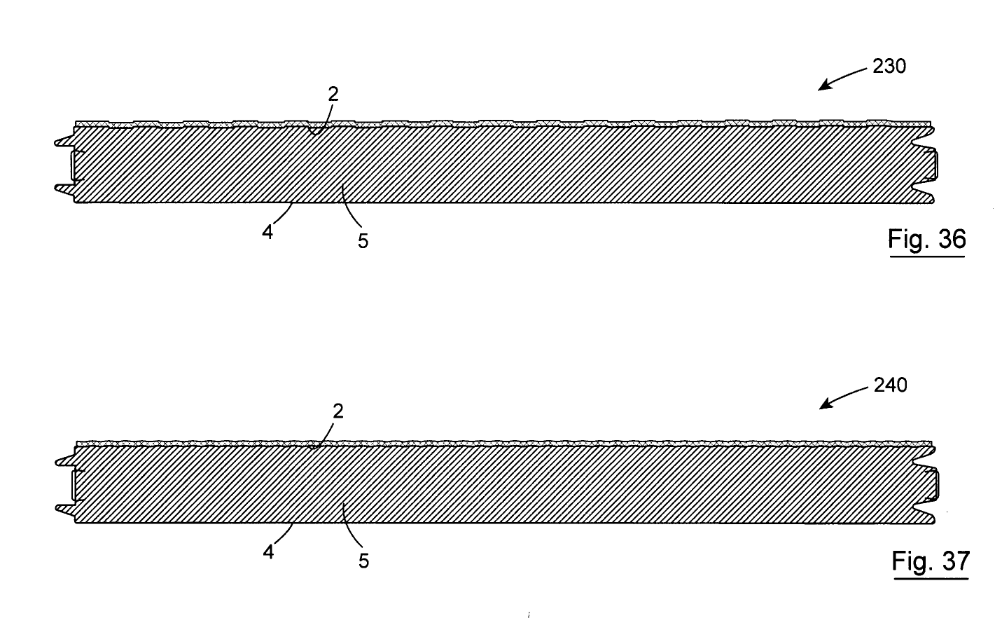

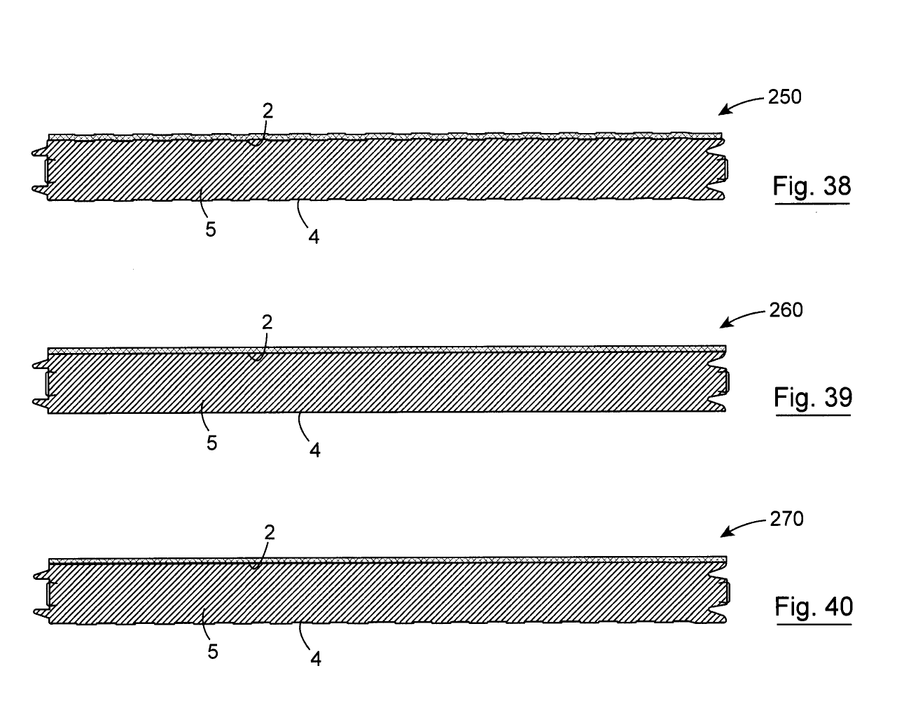

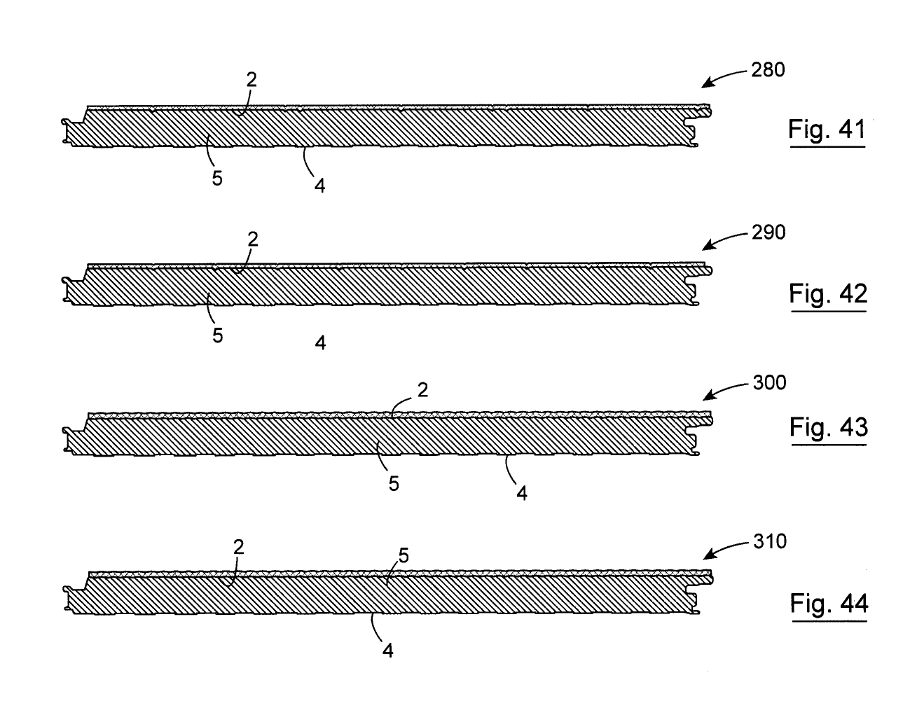

The panels 230 to 310 of FIGS. 36 to 44 respectively again illustrate the application of the invention to a wide range of panel types with different joint details and/or internal sheet and/or external sheet detailing/profiles.

The photovoltaic roofing panels of the invention may be connected to an electrical system using known technologies.

It will be appreciated that the invention may be applied to a wide range of panels including roof panels, wall panels, and/or floor panels. Maximum solar efficiency is however generally achieved by covering south facing portions of a building with roof panels of the invention.

The panels may be used to construct part of or all of the building envelope including part or all of one or more of the roof, walls and floor.

Various aspects described with reference to one embodiment may be utilised, as appropriate, with another embodiment. By way of example a plurality of separate voltaic units such as described with reference to FIGS. 10 to 17 may be utilised in any of the panels of FIGS. 18 to 44.

Many variations on the embodiments described will be readily apparent. Accordingly the invention is not limited to the embodiments hereinbefore described which may be varied in detail.

1-39. (canceled)

40. A composite insulating panel comprising:—
an external sheet;
an internal sheet;
an insulating body between the external sheet and the internal sheet, and
a photovoltaic solar collector sheet laminated to the external surface of the external sheet.

41. The panel as claimed in claim 40 comprising a translucent cover for the photovoltaic sheet.

42. The panel as claimed in claim 41 comprising an adhesive layer between the photovoltaic sheet and the cover.

43. The panel as claimed in claim 40 comprising an adhesive layer between the photovoltaic sheet and the external sheet.

44. The panel as claimed in claim 40 wherein the solar collector comprises a photovoltaic sheet, a translucent cover for the photovoltaic sheet, a first adhesive layer between one side of the photovoltaic sheet and the cover layer, and a second adhesive layer on the other side of the photovoltaic sheet.

45. The panel as claimed in claim 42 wherein the adhesive layer(s) is of a hot melt adhesive.

46. The panel as claimed in claim 42 wherein the adhesive layer(s) is of an ethylene vinyl acetate (EVA) material.

47. The panel as claimed in claim 43 wherein the adhesive layer between the external sheet and the photovoltaic sheet comprises a thermoplastic polyurethane (TPU) adhesive.

48. The panel as claimed in claim 40 wherein the translucent cover is of a plastics material.

49. The panel as claimed in claim 40 wherein the translucent cover is of an ethylene tetrafluoroethylene (ETFE) material.

50. The panel as claimed in claim 40 wherein the external sheet comprises a plurality of longitudinally extending ribs.

51. The panel as claimed in claim 50 wherein the photovoltaic sheet follows the contours of the ribs.

52. The panel as claimed in claim 40 comprising a plurality of photovoltaic solar collector sheets laminated to the external sheet of the panel.

53. The panel as claimed in claim 52 wherein the photovoltaic sheets are spaced-apart along and/or across the external sheet of the panel, at least some of the photovoltaic sheets being electrically interconnected.

54. The panel as claimed in claim 53 wherein the external sheet of the panel comprises a plurality of raised projections and the photovoltaic sheets are located between the projections.

55. The panel as claimed in claim 54 wherein the raised projections extend longitudinally along the length of the panel.

56. The panel as claimed in claim 54 wherein the raised projections comprise raised crowns.

57. The panel as claimed in claim 56 wherein the raised crowns are of generally trapezoidal form.

58. The panel as claimed in claim 54 wherein the raised projections comprise a side underlap projection and a side overlap projection for jointing adjacent panels.

59. The panel as claimed in claim 50 wherein the external sheet comprises a male projecting part and a female recess part for jointing adjacent panels.

60. The panel as claimed in claim 50 wherein the internal sheet comprises a male projecting part and a female recess part for jointing adjacent panels.

61. The panel as claimed in claim 50 wherein the insulating body comprises a plurality of longitudinally extending conduit means.

62. The panel as claimed in claim 61 wherein the external sheet comprises raised projections extending longitudinally along the length of the panel and the conduit means is defined in part by the inner face of the raised projection.

63. The panel as claimed in claim 40 wherein the insulating body comprises a foam.

64. The panel as claimed in claim 63 wherein the foam comprises a polyisocyanurate foam material.

65. The panel as claimed in claim 63 wherein the foam comprises a phenolic foam material.

66. The panel as claimed in claim 50 wherein the external sheet comprises a steel material.

67. The panel as claimed in claim 50 wherein the internal sheet comprises a metallic material.

68. The panel as claimed in claim 40 wherein the internal sheet comprises a steel material.

69. The panel as claimed in claim 40 wherein the panel comprises a roof panel.

70. A method for manufacturing a composite insulated panel with a photovoltaic solar collector sheet attached thereto comprising the steps of:—
providing an insulation panel comprising an external sheet, an internal sheet and an insulating body between the external sheet and the internal sheet; and
laminating a solar collector sheet to the external sheet of the panel.
